(19) United States
(12) Patent Application Publication
(10) Pub. No.: US 2004/0257064 A1
(43) Pub. Date: Dec. 23, 2004

(54) Device for automatically detecting harmful electromagnetic wave

(76) Inventor: Hiroshi Ito, Tokyo (JP)

Correspondence Address: HIROSHI ITO, 2-18-15 MIDDRIGADKA MEGURO, TOKYO, 152-0034, JP

(21) Appl. No.: 10/489,624

(22) PCT Filed: Dec. 14, 2001
(86) PCT No.: PCT/JP01/10949

(30) Foreign Application Priority Data
Oct. 17, 2001 (JP) 2001-353863

(51) Int. Cl. G01R 1/00

(52) U.S. Cl. 324/158.1

(57) ABSTRACT

Harmful electromagnetic wave that is emitted from mobile phone and computers, are sometime causing malfunctions on general delicate electronic devices. This is a device to give warnings against the bearing and intrusion of them, and that enables users to have effective application with low cost and with low nuisance warning rate by a feature which gives selectable warning threshold level for the best for each frequency band according to the reference of electromagnetic wave level which was measured and memorized as a circumstance data in the area of the first stage at the system application.

When a harmful electromagnetic wave were detected, this system gives the radiator automatic announcement to put them off and also gives indications such as location, intensity and the kind of the device from its experiences.

### TECHNICAL FIELD

The rate of unexpected malfunctions of electronic devises and computers which works with very low electrical current are glowing up in the resent condition which, mobile phone and mobile computer are inundating, and is coming up to give influences to the important field that relates lives of people. This invention is to inform applicable people of invasion and bearing of harmful wave into the area such as aircraft, boarding gate of flight, hospital and area that delicate electronic device and computer are being operated.

### BACKGROUND ART

In the circumstances that new technologies of mobile phone and mobile computer are being developed rapidly, the harmful electromagnetic wave unconsciously radiated from them are causing malfunctions in many fields of general computers and delicate electronic devices which were not incorporated features to protect those interference satisfactory.

Especially, in a specified area that people are prohibited to use mobile phone and that ordinary people gets in, it is a fact today that the bad influences caused by them are still happening frequently because of their forgetting to cut them off.

### DISCLOSURE OF THE INVENTION

This device was designed for easy application to users needs with low cost and with low nuisance warning rate by the feature which gives selectable warning threshold level for the best for each frequency band according to the reference of electromagnetic wave level which was measured and memorized as a circumstance data in the area of the first stage at the system application.

When a harmful electromagnetic wave were detected, this system gives the radiator automatic announcement to put them off and gives indications such as location, intensity and the kind of the device from its experiences to the applicable stuff for complementary actions to stop source of radiation easily.

### BRIEF DESCRIPTION OF THE DRAWINGS

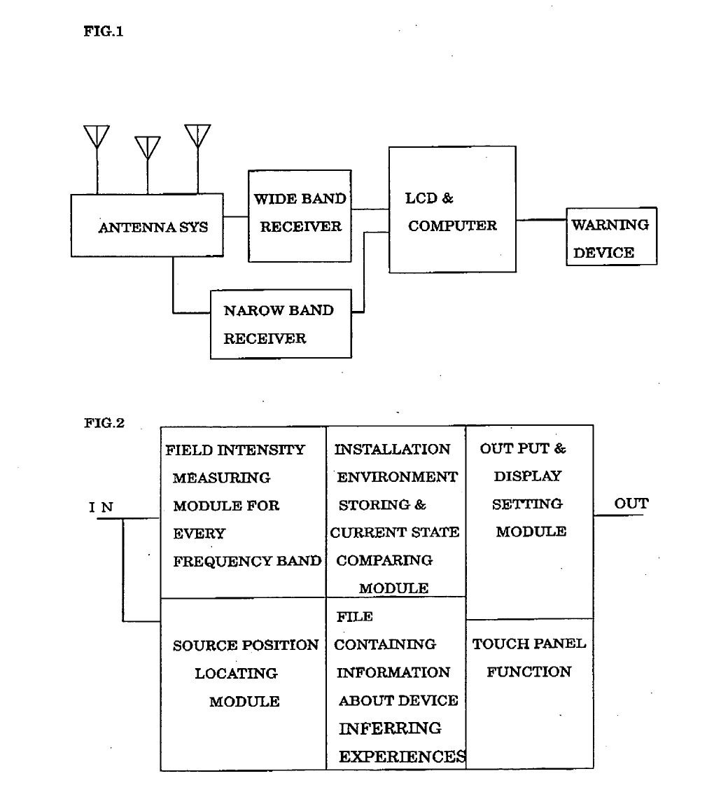

Total construction and hook up of the System is as shown in FIG. 1 and

functional construction of inside computer is constructed from six main parts as shown in FIG. 2.

### BEST MODE FOR CARRYING OUT THE INVENTION

The device of this invention is to be located in an area that many ordinary people will get in such as cabin of aircraft and hospital, measuring and memorizing electromagnetic wave level only in original circumstances, apply warning threshold level with some margin on it. This device gives warning against coming in of them, gives announcement to them to put the source of it off, and far the more, gives stuff who are in charge of protection against invasion of it, information about the location of the source and name of the presumable device. Thus, this device is used to protect malfunctions of delicate electronic devices and computers that are sensitive to these harmful electromagnetic wave in the area. With inputting of the name of experienced device to the system, this system introduce it into the experienced file in the applied circumstance to accurate the probability of the presumable device later and also possibly introduce it into the noise level of the installed circumstances. Also, detected data is functionally recorded any time and utilized to investigation and duplication of the phenomenon here after.

### INDUSTRIAL APPLICABILITY

Among general delicate electronic devices and computers, it is very rare that malfunctions caused by electromagnetic wave which is transmitted from mobile phone and mobile computer were took into its design consideration from the beginning.

It is forecasted that unforeseen malfunctions of computers and delicate electronic devices will be probable more and more because they are becoming lesser electrical current while the frequency of mobile phone is changing and coming out of new devices which radiates harmful wave is highly probable.

This system, locating in a area which malfunction of it should be firmly avoided and detecting the invasion and bearing of those electromagnetic wave and giving warnings of it, protect malfunctions which should not happen on computer and delicate electronic devices which we rely upon more and more in future.

I claim:

1. DEVICE FOR AUTOMATICALLY DETECTING HARMFUL ELECTROMAGNETIC WAVE which can be easily applied to any necessary circumstance with the feature of application of pre-measured and memorized electromagnetic wave level of initial and non trouble circumstance of the area and with the feature of applying some margin on the initial pre-measured level to define warning threshold level for each necessary frequency band in order to detect bearing and intrusion of harmful electromagnetic wave which is probable to cause of malfunction on the electronic devices and computers.
